(19) United States
(12) Patent Application Publication
(10) Pub. No.: US 2025/0169228 A1
(43) Pub. Date: May 22, 2025

(54) METHOD OF MANUFACTURING A SEMICONDUCTOR STRUCTURE AND SEMICONDUCTOR STRUCTURE

(71) Applicant: ams-OSRAM International GmbH, Regensburg (DE)

(72) Inventors: Andreas Ploessl, Regensburg (DE); Adrian Avramescu, Regensburg (DE)

(21) Appl. No.: 18/839,951

(22) PCT Filed: Nov. 25, 2022
(86) PCT No.: PCT/EP2022/083368

§ 371 Date: Aug. 20, 2024

(30) Foreign Application Priority Data
Feb. 25, 2022 (DE) 102022104563.3

(51) Int. Cl. H10H 20/812; H10H 20/01

(52) U.S. Cl. CPC H10H 20/812; H10H 20/0137

(57) ABSTRACT

In an embodiment a method includes epitaxially depositing an epitaxial semiconductor layer sequence having at least one p-doped semiconductor layer including a p-dopant and a passivating agent, wet-chemical etching of the epitaxial semiconductor layer sequence so that degassing channels are formed along crystal defects in the epitaxial semiconductor layer sequence from a main surface of the epitaxial semiconductor layer sequence up to at least the p-doped semiconductor layer, and expelling the passivating agent from the epitaxial semiconductor layer sequence through the degassing channels.

### CROSS-REFERENCE TO RELATED APPLICATIONS

This patent application is a national phase filing under section 371 of PCT/EP2022/083368, filed Nov. 25, 2022, which claims the priority of German patent application 10 2022 104 563.3, filed Feb. 25, 2022, each of which is incorporated herein by reference in its entirety.

### TECHNICAL FIELD

A method of manufacturing a semiconductor structure and a semiconductor structure are provided.

### SUMMARY

Embodiments provide an improved method of manufacturing a semiconductor structure, in which, in particular, a passivating material is expelled from the semiconductor structure.

Further embodiments provide an improved semiconductor structure, in which, in particular, a passivating agent is expelled from the semiconductor structure.

According to an embodiment of the method of manufacturing a semiconductor structure, an epitaxial semiconductor layer sequence comprising at least one p-doped semiconductor layer comprising a p-dopant and a passivating agent is first deposited epitaxially. The epitaxial semiconductor layer sequence is preferably epitaxially grown on a growth substrate by metal-organic vapor phase epitaxy (MOCVD).

The epitaxial semiconductor layer sequence preferably comprises or consists of a III-V compound semiconductor material. A III-V compound semiconductor material comprises at least one element from the third main group, such as B, Al, Ga, In, and one element from the fifth main group, such as N, P, As. In particular, the term “III-V compound semiconductor material” comprises the group of binary, ternary, or quaternary compounds which include at least one element from the third main group and at least one element from the fifth main group, for example a nitride compound semiconductor material.

Nitride compound semiconductor materials are compound semiconductor materials that include nitrogen, such as the materials from the InₓAl_{y}Ga_{1-x-y}N system, with 0≤x≤1, 0≤y≤1, and x+y≤1. For example, gallium nitride with x=y=0 is a material from this system.

Such binary, ternary, or quaternary compounds may also comprise one or more dopants and additional components, for example.

During epitaxial growth of the epitaxial semiconductor layer sequence, formation of crystal defects is difficult or impossible to avoid. For example, a lack of lattice matching between the growth substrate and the epitaxial semiconductor layer sequence leads to strains in the epitaxial semiconductor layer sequence. These strains may be at least partially released by random formation of crystal defects during epitaxial growth. For example, threading dislocations arise as crystal defects in the epitaxial semiconductor layer sequence during epitaxial growth. Threading dislocations are also referred to as line dislocations. A threading dislocation is a disruption of a periodicity of the crystal lattice of the epitaxial semiconductor layer sequence that extends through the epitaxial semiconductor layer sequence along a line, hereinafter referred to as a dislocation line. Preferably, the dislocation line extends through the epitaxial semiconductor layer sequence in a growth direction. In particular, an arrangement of the crystal defects in the epitaxial semiconductor layer sequence is random.

The threading dislocations may, for example, comprise a screw component or may be formed as screw dislocations. In a screw dislocation, crystal planes intersected by the dislocation line are connected to each other in a helical shape. If, for example, the dislocation line is circled along a crystal plane arranged perpendicular to the dislocation line, a displacement occurs in the direction of the dislocation line. The displacement resulting from circling the dislocation line once along a crystal plane is referred to as the Burgers vector. Screw dislocations are threading dislocations that may be characterized by a Burgers vector parallel to the dislocation line. In contrast, the Burgers vector for step dislocations is perpendicular to the dislocation line. Threading dislocations having a screw component comprise a Burgers vector that points at least partially in the direction of the dislocation line. In particular, screw dislocations and threading dislocations having a screw component comprise a hollow core.

The p-doped semiconductor layer is preferably a buried semiconductor layer. In this instance and in the following, a semiconductor layer is referred to as “buried” if at least one further semiconductor layer is arranged both above and below the buried semiconductor layer in the growth direction of the epitaxial semiconductor layer sequence.

The p-dopant serves as an electron acceptor and is introduced into the p-doped semiconductor layer during epitaxial growth. The p-dopant increases the charge carrier density of freely movable holes in the p-doped semiconductor layer.

The passivating agent consists of foreign atoms that are not intentionally introduced into the epitaxial semiconductor layer sequence, particularly during epitaxial growth. For example, it is difficult or impossible, due to nature of the method, to avoid introducing the passivating agent into the epitaxial semiconductor layer sequence. In particular, the passivating agent has a compensating effect on the p-dopant in the p-doped semiconductor layer. For example, the passivating agent acts as an electron donor in the p-doped semiconductor layer and/or forms binding complexes with the p-dopant. In this way, the passivating agent reduces the charge carrier density of moving holes in the p-doped semiconductor layer. In particular, due to the passivating agent, the charge carrier density of movable holes in the p-doped semiconductor layer is lower than the charge carrier density expected by the nominal concentration of the p-dopant. For example, the passivating agent reduces the charge carrier density of moving holes in the p-doped semiconductor layer by up to three orders of magnitude, for example by a factor of 5000.

According to a further embodiment of the method, the epitaxial semiconductor layer sequence is etched by wet-chemical means so that degassing channels are formed along crystal defects in the epitaxial semiconductor layer sequence from a main surface of the epitaxial semiconductor layer sequence up to at least the p-doped semiconductor layer. In wet-chemical etching, a liquid etchant is applied to the epitaxial semiconductor layer sequence. The epitaxial semiconductor layer sequence may also be immersed in a liquid etchant. The liquid etchant, for example aqueous solutions of nitric acid or oxalic acid, is configured to dissolve atoms from the epitaxial semiconductor layer sequence and transport them away.

Preferably, the wet-chemical etching of the epitaxial semiconductor layer sequence is carried out from a main surface of the epitaxial semiconductor layer sequence facing away from the growth substrate. Alternatively or additionally, the epitaxial semiconductor layer sequence may be wet-chemically etched from a growth substrate side after removal of the growth substrate.

The wet chemical etching is more specifically configured to etch the epitaxial semiconductor layer sequence in the immediate vicinity of existing crystal defects in the epitaxial semiconductor layer sequence. The liquid etchant may, for example, penetrate into the epitaxial semiconductor layer sequence along threading dislocations that extend through the epitaxial semiconductor layer sequence and decompose the epitaxial semiconductor layer sequence in the immediate vicinity of the threading dislocations. More specifically, the liquid etchant may penetrate into threading dislocations that have a screw component or are formed as screw dislocations and thus comprise a hollow core.

The publication Massabuau et al., APL Mater. 8, 031115 (2020) describes threading dislocations in semiconductor layers of gallium nitride as channels for liquid etchants. The content of this publication is incorporated herein by reference in its entirety.

According to a further embodiment of the method, the passivating agent is expelled from the epitaxial semiconductor layer sequence through the degassing channels. For example, the epitaxial semiconductor layer sequence is baked so that the diffusivity of the passivating agent in the p-doped semiconductor layer is increased. This allows the passivating agent to outgas through the degassing channels and be transported away from the p-doped semiconductor layer. A small portion of the passivating agent may remain in the p-doped semiconductor layer. In particular, the at least partial expulsion of the passivating agent increases the charge carrier density of moving holes in the p-doped semiconductor layer.

According to a preferred embodiment, the method of manufacturing a semiconductor structure comprises the following steps:
epitaxially depositing the epitaxial semiconductor layer sequence comprising at least the p-doped semiconductor layer comprising the p-dopant and the passivating agent,
wet-chemical etching of the epitaxial semiconductor layer sequence, so that degassing channels are formed along crystal defects in the epitaxial semiconductor layer sequence from the main surface of the epitaxial semiconductor layer sequence up to at least the p-doped semiconductor layer,
expelling the passivating agent from the epitaxial semiconductor layer sequence through the degassing channels.

The above steps are preferably carried out in the order listed.

Especially during epitaxial growth of p-doped semiconductor layers made of gallium nitride by means of metal-organic vapor phase epitaxy, hydrogen is incorporated into the semiconductor layer, which acts as a passivating agent. To activate the p-dopant, the hydrogen must therefore be expelled from the p-doped semiconductor layer. However, this is difficult to do with buried p-doped semiconductor layers made of gallium nitride. More specifically, the hydrogen may not be expelled through n-doped semiconductor layers that are arranged above or below the p-doped semiconductor layer in the direction of growth.

For example, the hydrogen may be expelled by lateral diffusion along a main extension plane of the semiconductor layer. In this context and in the following, “lateral” refers to a direction perpendicular to the growth direction of the epitaxial semiconductor layer sequence. However, this is only possible for semiconductor structures of a small lateral extension of, for example, about 40 micrometers, as described in Wong et al., Appl. Phys. Express 14, 086502 (2021), the disclosure of which is incorporated herein by reference. More specifically, a process time to expel the hydrogen is proportional to a diffusion length of hydrogen in the p-doped semiconductor layer and therefore proportional to the lateral extent of the semiconductor structure.

Alternative epitaxy processes to MOCVD, such as molecular beam epitaxy, may also be used to minimize the incorporation of hydrogen. However, using these alternative processes would result in a loss of manufacturing advantages of MOCVD. Furthermore, degassing channels may be etched into the semiconductor structure using photolithographic processes, for example. More specifically, the degassing channels created in this process have large diameters of several hundred nanometers. In addition, the reactive ion etching processes required for such processes cause major damage to the side walls of the degassing channels.

The process described herein is based on the idea of gently expanding existing threading dislocations in the epitaxial semiconductor layer sequence by means of wet-chemical etching. This creates degassing channels through which the hydrogen may be efficiently removed after epitaxial growth.

According to a further embodiment of the method, the epitaxial semiconductor layer sequence comprises or consists of a nitride compound semiconductor material. The p-dopant in the p-doped semiconductor layer is magnesium, for example. The passivating material is hydrogen, for example, which is introduced into the epitaxial semiconductor layer sequence by metal-organic vapor phase epitaxy due to the nature of the method.

According to a further embodiment of the method, the epitaxial semiconductor layer sequence comprises an n-doped semiconductor layer which is arranged between the p-doped semiconductor layer and the main surface of the epitaxial semiconductor layer sequence. More specifically, the p-doped semiconductor layer is a buried semiconductor layer, above which an n-doped semiconductor layer is arranged in the growth direction. If the semiconductor layer sequence consists of a nitride compound semiconductor material and the passivating agent is hydrogen, the hydrogen may, in particular, not be expelled through the n-doped semiconductor layer.

According to a further embodiment of the method, the crystal defects are formed as threading dislocations in the epitaxial semiconductor layer sequence during epitaxial deposition and have a main direction of extension corresponding to the growth direction of the epitaxial semiconductor layer sequence. More specifically, the threading dislocation comprises a screw component or is formed as a screw dislocation and comprises a hollow core. The threading dislocation propagates along the dislocation line in the epitaxial semiconductor layer sequence.

The threading dislocation spreads through the epitaxial semiconductor layer sequence in the growth direction in particular. The threading dislocation may also propagate in a lateral direction through the epitaxial semiconductor layer sequence during epitaxial growth of the epitaxial semiconductor layer sequence. The main direction of extension thus indicates a preferred propagation direction of the threading dislocation, whereby the propagation direction of the threading dislocation may deviate from the main extension direction in a lateral direction.

According to a further embodiment of the method, the threading dislocations are formed as screw dislocations having a hollow core. More specifically, the threading dislocations comprise a screw component, with the Burgers vector pointing at least partially in the direction of the dislocation line. Therefore, the Burgers vector preferably comprises a component parallel to the direction of growth.

According to a further embodiment of the method, the wet-chemical etching is an electrochemical etching process in which the degassing channels are formed by expanding the threading dislocations. In the electrochemical etching process, the epitaxial semiconductor layer sequence is introduced into a liquid etchant. More specifically, the liquid etchant is an electrolyte solution that may be basic, acidic or neutral and is configured to transport electrical charge carriers. Examples of liquid etching agents are aqueous solutions of potassium hydroxide, sodium hydroxide, hydrochloric acid, oxalic acid, nitric acid, sulphuric acid, clover acid, succinic acid or a saline solution. In the electrochemical etching process, the epitaxial semiconductor layer sequence is connected to one pole of an electrical voltage source via an electrical contact, while an opposite pole of the electrical voltage source is connected to an inert electrode introduced into the liquid etchant. The electrode comprises or consists of platinum, for example.

An electrical voltage difference between the epitaxial semiconductor layer sequence and the inert electrode causes an electrical current to flow between the semiconductor layer sequence and the electrode, the epitaxial semiconductor layer sequence being at least partially decomposed by a combination of electrical and chemical processes. In this process, an etching rate depends on the electrical voltage difference applied and on a dopant concentration in the epitaxial semiconductor layer sequence, for example.

According to a further embodiment of the method, the epitaxial semiconductor layer sequence is irradiated with electromagnetic radiation during electrochemical etching. More specifically, the electromagnetic radiation generates a photocurrent in the epitaxial semiconductor layer sequence, which supports the electrochemical etching.

According to a further embodiment of the method, the electrochemical etching of the epitaxial semiconductor layer sequence is carried out in the absence of light. In other words, the epitaxial semiconductor layer sequence is not irradiated with electromagnetic radiation during electrochemical etching. In that case, no additional photocurrent is generated that influences the etching rate.

According to a further embodiment of the method, the p-dopant is activated by expelling the passivating agent. For example, expulsion of the passivating agent breaks up binding complexes between the p-dopant and the passivating agent. Furthermore, expelling the passivating agent reduces compensation of the p-dopant. The activation of the p-dopant by expelling the passivating agent therefore results in an increase in the charge carrier density of movable holes in the p-doped semiconductor layer.

According to a further embodiment of the method, the main surface of the epitaxial semiconductor layer sequence is formed by a surface of an undoped top layer. In other words, in a final step of epitaxially depositing the epitaxial semiconductor layer sequence, an undoped top layer is epitaxially grown. More specifically, the undoped top layer is largely inert to the liquid etchant. Therefore, the main surface of the epitaxial semiconductor layer sequence is protected by the undoped top layer during wet chemical etching. However, the liquid etchant may penetrate the epitaxial semiconductor layer sequence through threading dislocations, which also extend through the undoped top layer, and may expand the threading dislocations to form degassing channels.

The undoped top layer may, after wet-chemical etching, remain in place as part of the epitaxial semiconductor layer sequence or may be removed. For example, the top layer forms a protection for the semiconductor layer sequence during further process steps. Preferably, the undoped top layer is at least partially removed before, for example, a metallic contact layer is applied to the semiconductor layer sequence. For example, the top layer is removed by wet- or dry-chemical means. In particular, dry-chemical removal of the top layer is possible in-situ in an epitaxial deposition system.

According to a further embodiment of the method, the degassing channels are at least partially filled with a dielectric after the passivating agent has been expelled. For example, the degassing channels are at least partially filled and/or at least partially sealed with a dielectric, for example aluminum oxide or silicon dioxide, by atomic layer deposition or by gas phase deposition. For example, walls, in particular side walls, of the degassing channels are lined with the dielectric. The dielectric is electrically insulating and is more specifically, configured to prevent electrical short circuits within the epitaxial semiconductor layer sequence, which may be caused by impurities in the degassing channels, for example.

Furthermore, a semiconductor structure is disclosed. More specifically, the semiconductor structure may be manufactured using the method described herein. All features of the method of manufacturing a semiconductor structure are also disclosed for the semiconductor structure and vice versa.

According to one embodiment, the semiconductor structure comprises an epitaxial semiconductor layer sequence comprising at least one p-doped semiconductor layer. The epitaxial semiconductor layer sequence preferably comprises a nitride compound semiconductor material. More specifically, the p-doped semiconductor layer is a buried semiconductor layer. Preferably, an n-doped semiconductor layer is arranged after the p-doped semiconductor layer in the growth direction of the epitaxial semiconductor layer sequence.

According to a further embodiment, the semiconductor structure comprises a plurality of degassing channels. The degassing channels are widened crystal defects. More specifically, the crystal defects are threading dislocations comprising a screw component or being formed as screw dislocations and having a hollow core.

The degassing channels extend in the epitaxial semiconductor layer sequence from a main surface of the epitaxial semiconductor layer sequence at least up to the p-doped semiconductor layer. In particular, a main direction of extension of the degassing channels corresponds to the growth direction of the epitaxial semiconductor layer sequence.

According to a preferred embodiment, the semiconductor structure comprises the following features:
the epitaxial semiconductor layer sequence comprising at least one p-doped semiconductor layer,
the plurality of degassing channels, wherein
the degassing channels are widened crystal defects, and
the degassing channels in the epitaxial semiconductor layer sequence extend from a main surface of the epitaxial semiconductor layer sequence up to at least the p-doped semiconductor layer.

According to a further embodiment of the semiconductor structure, the epitaxial semiconductor layer sequence comprises an active layer which is configured to generate and/or absorb electromagnetic radiation. More specifically, the semiconductor structure is an optoelectronic semiconductor structure. For example, the semiconductor structure is part of a light-emitting diode, a laser diode, a photodiode, or a phototransistor. More specifically, the semiconductor structure is configured to generate or absorb electromagnetic radiation in a spectral range between infrared light and ultraviolet light.

More specifically, the active layer comprises a pn junction. The pn junction may be configured as a quantum well structure or a multiple quantum well structure. In the context of the present application, the term quantum well structure includes more specifically any structure in which charge carriers undergo quantization of their energy states through confinement. In particular, the term quantum well structure does not include any indication of the dimensionality of the quantization. Therefore, it includes, among other things, quantum wells, quantum wires, and quantum dots as well as any combination of these structures.

According to a further embodiment of the semiconductor structure, the epitaxial semiconductor layer sequence comprises pores that are arranged laterally around the degassing channels. Preferably, a pore is spatially directly connected to at least one degassing channel. The pores extend laterally into the epitaxial semiconductor layer sequence around the degassing channels, like polyps, for example. More specifically, the pores are formed due to the crystal defects expanding during wet-chemical etching of a doped semiconductor layer. A porosity of the epitaxial semiconductor layer sequence may be set, for example, by suitable selection of process parameters, for example a temperature and/or an etching duration, during the wet-chemical etching of the epitaxial semiconductor layer sequence.

According to a further embodiment of the semiconductor structure, the degassing channels penetrate the p-doped semiconductor layer, preferably completely. Degassing channels that penetrate the p-doped semiconductor layer improve the expulsion of the passivating agent from the p-doped semiconductor layer.

According to a further embodiment of the semiconductor structure, the p-doped semiconductor layer forms a layer of a tunnel junction. More specifically, the p-doped semiconductor layer is a highly doped semiconductor layer having a concentration of the p-dopant of at least 10¹⁹ per cubic centimeter. For example, the tunnel junction is configured as a hole injection layer to reduce high electrical resistance of thick p-doped layers in nitride compound semiconductor materials. The tunnel junction may also be formed as an anode-side metal-semiconductor contact in order to avoid high contact resistance between a metal of a terminal contact and a p-doped layer of a nitride compound semiconductor material. Furthermore, the tunnel junction may be configured for electrically connecting serially stacked active layers in the epitaxial semiconductor layer sequence, for example a light-emitting diode.

According to a further embodiment of the semiconductor structure, the epitaxial semiconductor layer sequence comprises two active layers for generating electromagnetic radiation, between which the tunnel junction is arranged. In this way, for example, the luminance of a light-emitting diode may be increased without increasing the operating current. To power such a semiconductor structure, a forward voltage approximately twice as high as in the case of a single active layer is required, which advantageously increases the range of suitable driver devices.

The semiconductor structure may also comprise more than two active layers, with a tunnel junction being arranged between two adjacent active layers. The active layers may be configured to emit electromagnetic radiation in different spectral ranges. For example, the semiconductor structure comprises three active layers that are configured to emit electromagnetic radiation in the blue, green and red spectral ranges. Preferably, the active layers may be controlled independently of each other. The semiconductor structure is therefore, for example, an epitaxially stacked RGB pixel.

According to a further embodiment of the semiconductor structure, degassing channels in the region of an n-doped semiconductor layer of the tunnel junction have a greater lateral extent than in the rest of the epitaxial semiconductor layer sequence. In particular, a porosity of the n-doped semiconductor layer of the tunnel junction is greater than in the rest of the epitaxial semiconductor layer sequence. Therefore, if an electrical voltage is applied to the semiconductor structure, a geometric field amplification of the electric field in the n-doped semiconductor layer of the tunnel junction occurs. For example, due to the greater lateral expansion of the degassing channels, tips may be formed in the n-doped semiconductor layer of the tunnel junction, at which an increase in the electric field occurs. This particularly promotes tunneling of electrons at the tunnel junction.

According to a further embodiment of the semiconductor structure, the degassing channels are at least partially filled with a dielectric. The dielectric comprises aluminum oxide or silicon dioxide, for example, or is formed from one of these materials.

According to a further embodiment of the semiconductor structure, the degassing channels have a diameter of between 1 nanometer and 250 nanometers inclusive, preferably between 1 nanometer and 50 nanometers inclusive, more preferably between 1 nanometer and 20 nanometers inclusive.

According to a further embodiment of the semiconductor structure, the degassing channels have an areal density of between 10⁵ per square centimeter and 10⁸ per square centimeter. A relatively high areal density of the crystal defects and therefore of the degassing channels reduces the time required to expel the passivating agent.

### BRIEF DESCRIPTION OF THE DRAWINGS

Further advantageous embodiments and further embodiments of the method of manufacturing the semiconductor structure and of the semiconductor structure will become apparent from the embodiments described below in conjunction with the figures.

FIGS. 1-7 show schematic sectional views of stages of a method of manufacturing a semiconductor structure according to an embodiment;

FIGS. 8-10 show schematic sectional views of semiconductor structures according to various embodiments;

FIG. 11 shows an example of a scanning electron micrograph of an epitaxial semiconductor layer sequence;

FIG. 12 shows a schematic perspective view of a screw dislocation; and

FIG. 13 shows a schematic section of a semiconductor structure according to a further embodiment.

Elements that are identical, similar, or have the same effect are denoted with the same reference numerals throughout the figures. The figures and the proportions of the elements shown in the figures are not to be regarded as true to scale. Rather, individual elements, in particular layer thicknesses, may be shown in exaggerated size for better visualization and/or understanding.

### DETAILED DESCRIPTION OF ILLUSTRATIVE EMBODIMENTS

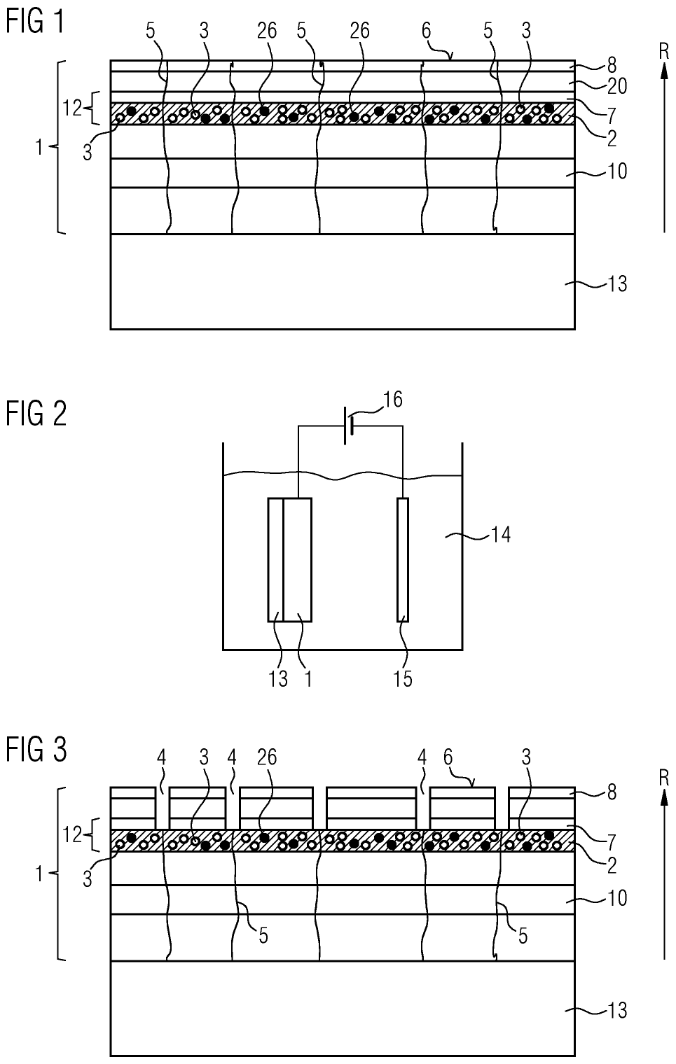

In the method of manufacturing a semiconductor structure according to the embodiment of FIGS. 1 to 7, an epitaxial semiconductor layer sequence 1 is first grown epitaxially on a growth substrate 13 (FIG. 1). The growth substrate 13 is formed from sapphire, silicon, gallium nitride, silicon carbide or aluminum nitride, for example, or comprises at least one of these materials. The epitaxial semiconductor layer sequence 1 comprises a nitride compound semiconductor material and an active layer 10 for generating electromagnetic radiation. The semiconductor structure is part of a light-emitting diode or a laser diode, for example.

The epitaxial semiconductor layer sequence 1 comprises a tunnel junction 12 which is arranged after the active layer 10 in a growth direction R of the epitaxial semiconductor layer sequence 1. The tunnel junction 12 comprises an n-doped semiconductor layer 7 and a p-doped semiconductor layer 2, with the p-doped semiconductor layer 2 facing the active layer 10. More specifically, the semiconductor layer arranged after the tunnel junction 12 in the growth direction R is an n-doped current spreading layer 20. For example, the n-doped current spreading layer 20 is an n-doped anode contact layer. The semiconductor layers 2, 7 of the tunnel junction 12 are heavily doped and have a dopant concentration of at least 10¹⁹ per cubic centimeter. Compared to a semiconductor structure without a tunnel junction 12, which, in particular, comprises a p-doped anode contact layer, the semiconductor structure described herein comprising an n-doped anode contact layer 20 advantageously has a lower contact resistance to a metallic terminal contact.

The epitaxial semiconductor layer sequence 1 comprises an undoped top layer 8, which is arranged as the final layer in the growth direction R and forms a main surface 6 of the epitaxial semiconductor layer sequence 1. The undoped top layer 8 is largely inert to a liquid etchant 14 and protects the surface of the epitaxial semiconductor layer sequence 1 during subsequent wet-chemical etching.

More specifically, the epitaxial semiconductor layer sequence 1 is deposited on the growth substrate 13 using a metal-organic vapor phase epitaxy process. As a result, hydrogen is incorporated into the epitaxial semiconductor layer sequence 1 due to the nature of the process. The hydrogen incorporated into the p-doped semiconductor layer 2 acts as a passivating agent 3 which at least partially compensates for the p-dopant 26 in the p-doped semiconductor layer 2. The p-doped semiconductor layer 2 therefore has a lower charge carrier density of movable holes than would be expected from a nominal concentration of the p-dopant.

The epitaxial semiconductor layer sequence 1 comprises crystal defects 5 which are more specifically formed as threading dislocations 5 and have a main direction of extension in the growth direction R of the epitaxial semiconductor layer sequence 1. The threading dislocations 5 form, for example, as a result of a mismatch between a crystal lattice of the growth substrate 13 and a crystal lattice of the epitaxial semiconductor layer sequence 1. During epitaxial growth of the epitaxial semiconductor layer sequence 1, the crystal defects 5 propagate particularly in the growth direction R. The threading dislocations 5 have an areal density of between 10⁶ cm⁻² and 10⁸ cm⁻², for example. At least some of the threading dislocations 5 are formed as screw dislocations 22 which comprise a hollow core 24.

FIG. 2 shows a schematic representation of a next step in the method of manufacturing a semiconductor structure, in which the epitaxial semiconductor layer sequence 1 is electrochemically etched. For this purpose, the epitaxial semiconductor layer sequence 1 on the growth substrate 13 is immersed in a bath of a liquid etchant 14. The liquid etchant 14 comprises hydrochloric acid or oxalic acid, for example. Alternatively, the liquid etchant 14 may also be basic or neutral. Furthermore, an inert electrode 15, for example made of platinum, is immersed in the liquid etchant 14. The epitaxial semiconductor layer sequence 1 and the electrode 15 are connected to opposite poles of an electrical voltage source 16.

During electrochemical etching of the epitaxial semiconductor layer sequence 1, the liquid etchant 14 penetrates the epitaxial semiconductor layer sequence 1 through the threading dislocations 5 and at least partially dissolves the epitaxial semiconductor layer sequence 1 in the immediate vicinity of the threading dislocations 5. As a result, the threading dislocations 5 are widened, and degassing channels 4 are formed along the threading dislocations 5.

FIG. 3 shows a schematic representation of a stage of the semiconductor structure after electrochemical etching. At this point, degassing channels 4 have formed along the threading dislocations 5 from a main surface 6 of the epitaxial semiconductor layer sequence 1 to the p-doped semiconductor layer 2. A depth of the degassing channels 4 may be set, for example, by a suitably selected etching time. The degassing channels 4 have an average diameter of between 1 nanometer and 20 nanometers inclusive.

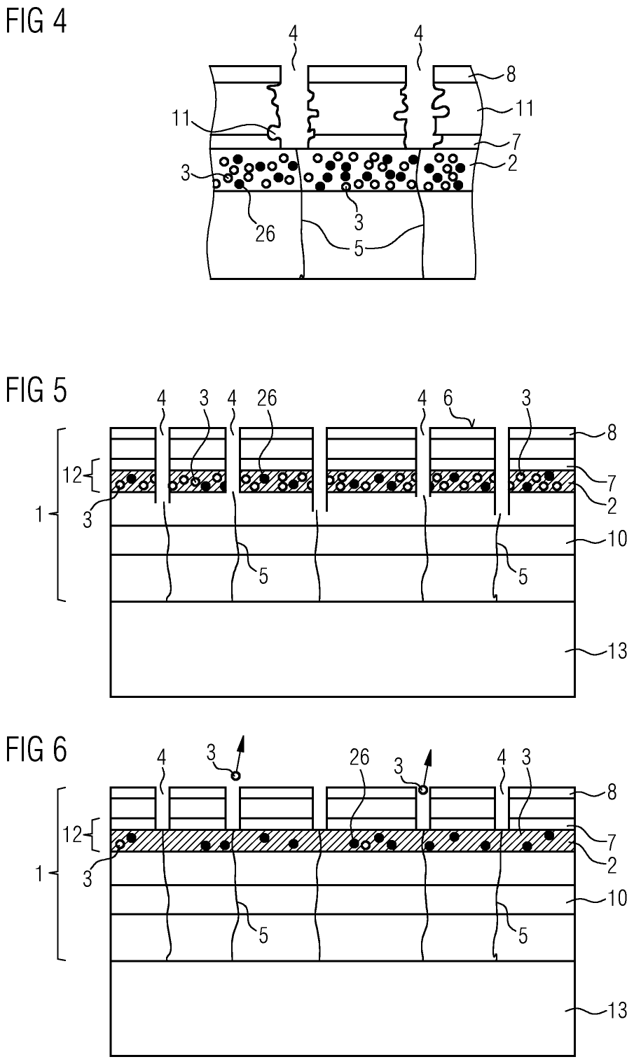

FIG. 4 shows an enlarged view of the degassing channels 4 of FIG. 3. More specifically, a patterning of the side walls of the degassing channels 4 is shown, which is formed by the electrochemical etching. For example, pores 11 are formed in the epitaxial semiconductor layer sequence 1, which are arranged laterally around the degassing channels 4. A porosity of the epitaxial semiconductor layers through which the degassing channels 4 extend may be adjusted, for example, by suitably selecting the parameters of the electrochemical etching.

FIG. 5 shows another example of a stage of a semiconductor structure after electrochemical etching. In contrast to the semiconductor structure in FIG. 4, the degassing channels 4 here penetrate the p-doped semiconductor layer 2. This may, for example, facilitate the expulsion of the passivating material 3 from the p-doped semiconductor layer 2 in a subsequent process step.

FIG. 6 shows a semiconductor structure after the passivating agent 3 has been expelled. More specifically, the semiconductor structure is baked, thereby increasing the diffusivity of the passivating agent 3 in the p-doped semiconductor layer 2. In particular, the passivating agent 3 exits the epitaxial semiconductor layer sequence 1 through the degassing channels 4, wherein a small proportion of the passivating agent 3 may remain in the p-doped semiconductor layer 2.

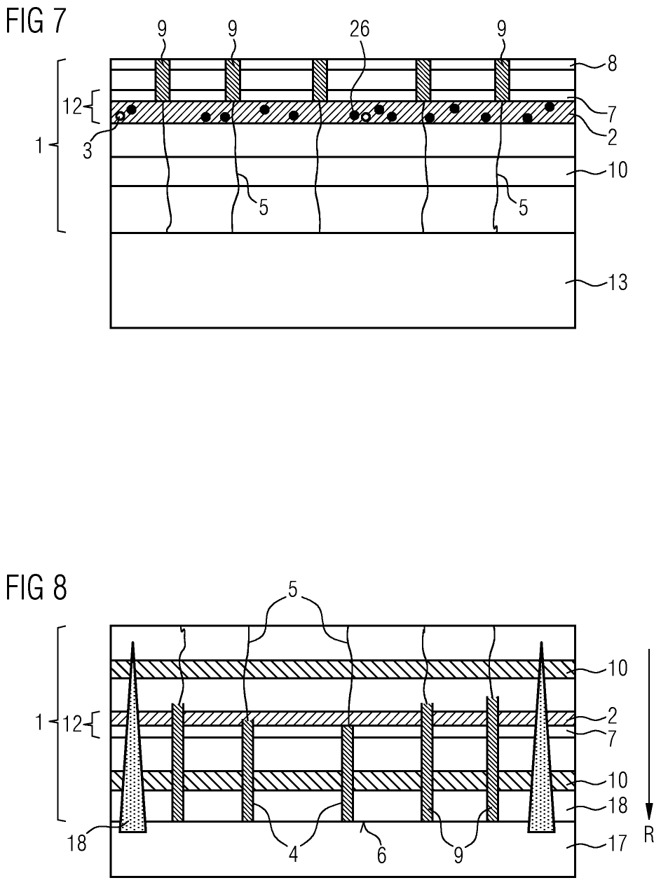

FIG. 7 shows the semiconductor structure after a further process step in which the degassing channels 4 are at least partially sealed with a dielectric 9, in particular aluminum oxide or silicon dioxide. The dielectric 9 is introduced into the degassing channels 4 by atomic layer deposition or vapor deposition, for example. More specifically, the dielectric 9 is configured to reduce the probability of an electrical short circuit in the epitaxial semiconductor layer sequence 1, which may be caused, for example, by incorporation of impurities in the degassing channels 4.

FIG. 8 shows a schematic sectional view of a semiconductor structure comprising an epitaxial semiconductor layer sequence 1 which comprises two active layers 10. The two active layers 10 are configured to generate electromagnetic radiation and are formed as series-connected pn junctions. A tunnel junction 12 is arranged between the two active layers 10. The tunnel junction 12 comprises an n-doped semiconductor layer 7 and a p-doped semiconductor layer 2 of high dopant concentrations in order to minimize a series resistance of the tunnel junction 12.

Degassing channels 4 filled with a dielectric 9 extend along threading dislocations 5 from a main surface 6 of the epitaxial semiconductor layer sequence 1 through an active layer 10 at least as far as the p-doped semiconductor layer 2 of the tunnel junction 12. A diameter of the degassing channels 4 is 10 nanometers.

The semiconductor structure is a thin-film chip in which the epitaxial semiconductor layer sequence 1 is arranged on a carrier 17 and the growth substrate 13 is removed. Furthermore, the epitaxial semiconductor layer sequence 1 comprises via contacts 18 for electrical contacting of the active layers 10.

More specifically, the semiconductor structure shown in FIG. 8 is configured as a high-power luminescent diode having a lateral expansion of at least 2 millimetres. Due to this large lateral expansion of the semiconductor structure, lateral expulsion of the passivating agent 3 from the p-doped semiconductor layer 2 is not possible. Threading dislocations 5, which have been widened by the electrochemical etching process, form degassing channels 4 through which the passivating material 3 is expelled, particularly from the p-doped semiconductor layer 2 of the tunnel junction 12.

More specifically, the series connection of the two active layers 10 increases a luminance during operation of the semiconductor structure. Nevertheless, an operating current remains essentially the same compared to a semiconductor structure comprising only one active layer 10, while the operating voltage is approximately twice as high. This advantageously results in a larger range of suitable driver devices.

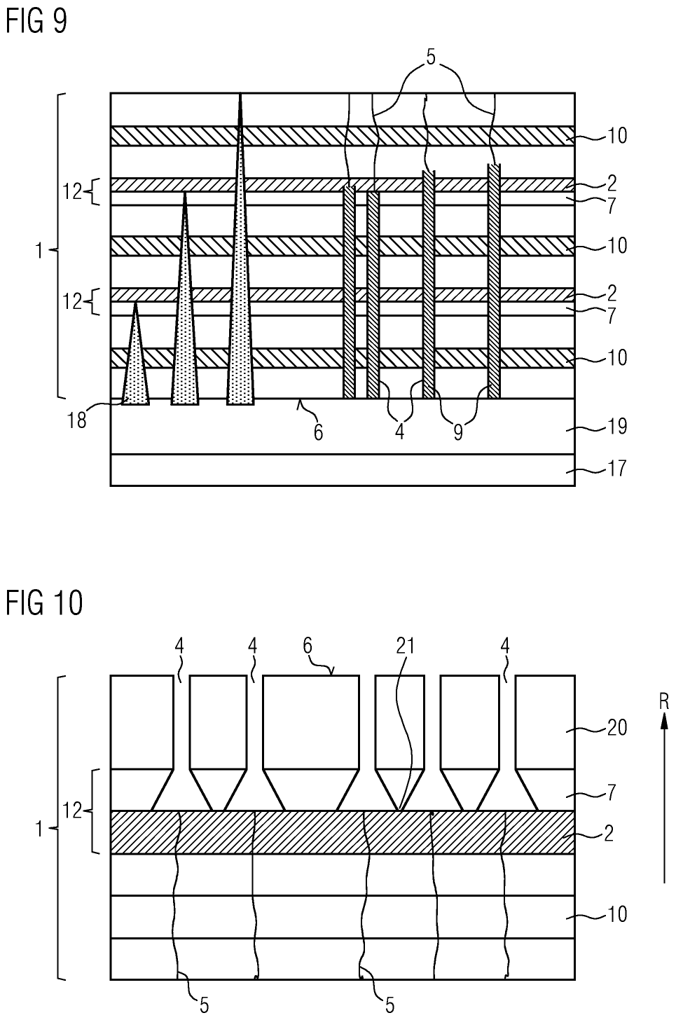

FIG. 9 shows another optoelectronic semiconductor structure comprising an epitaxial semiconductor layer sequence 1 which, in contrast to the semiconductor structure in FIG. 8, comprises three active layers 10. A tunnel junction 12 is arranged between respective adjacent active layers 10. Each of the active layers 10 is configured to generate electromagnetic radiation in a different spectral range. For example, an active layer 10 emits light in the red spectral range during operation, an active layer 10 emits light in the green spectral range, and an active layer 10 emits light in the blue spectral range. Via contacts 18 are configured for independent electrical contacting and therefore for individually controlling the three active layers 10. Therefore, the semiconductor structure shown in FIG. 9 forms a full-color LED that is formed as a thin-film chip. More specifically, the epitaxial semiconductor layer sequence 1 is arranged on a carrier 17, which comprises a drive circuit 19 for operating the active layers 10. The growth substrate 13 is has been removed from the epitaxial semiconductor layer sequence 1.

Degassing channels 4 sealed with a dielectric 9 extend from a main surface 6 of the epitaxial semiconductor layer sequence 1 along threading dislocations 5 through two active layers 10 and through both tunnel junctions 12. The degassing channels 4 are particularly configured to activate the p-dopant 3 in the p-doped semiconductor layers 2 of the two tunnel junctions 12.

FIG. 10 shows an embodiment of a semiconductor structure comprising an epitaxial semiconductor layer sequence 1 comprising an active layer 10 for generating electromagnetic radiation, a tunnel junction 12, and a current spreading layer 20. The tunnel junction 12 comprises a p-doped semiconductor layer 2 and an n-doped semiconductor layer 7, which have a higher dopant concentration than the other semiconductor layers of the epitaxial semiconductor layer sequence 1. The current spreading layer 20 is n-doped and arranged after the tunnel junction 12 in the growth direction R of the epitaxial semiconductor layer sequence 1. More specifically, the current expansion layer 20 has a lower dopant concentration than the tunnel junction 12. The current expansion layer 20 is configured as an n-doped anode contact layer to which, for example, a metallic contact layer may be applied for electrical contacting of the semiconductor structure.

The epitaxial semiconductor layer sequence 1 comprises degassing channels 4 which extend from a main surface 6 of the epitaxial semiconductor layer sequence 1 along threading dislocations 5 to the p-doped semiconductor layer 2 of the tunnel junction 12. Within the n-doped semiconductor layer 7 of the tunnel junction 12, the degassing channels 4 have a greater lateral expansion than in the current spreading layer 20. For example, due to the higher dopant concentration, a charge carrier density and therefore an etch rate during electrochemical etching is greater in the n-doped semiconductor layer 7 than in the current spreading layer 20. More specifically, the n-doped semiconductor layer 7 comprises pores 11 that may be created by the stronger etching in the lateral direction.

Due to the greater lateral expansion of the degassing channels 4 and/or a porosity of the n-doped semiconductor layer 7, tips 21 are formed in the n-doped semiconductor layer 7. When an electric field is applied to the semiconductor layer sequence 1, the tips 21 result in an increase in the electric field at the tunnel junction 12, which promotes tunneling of the charge carriers.

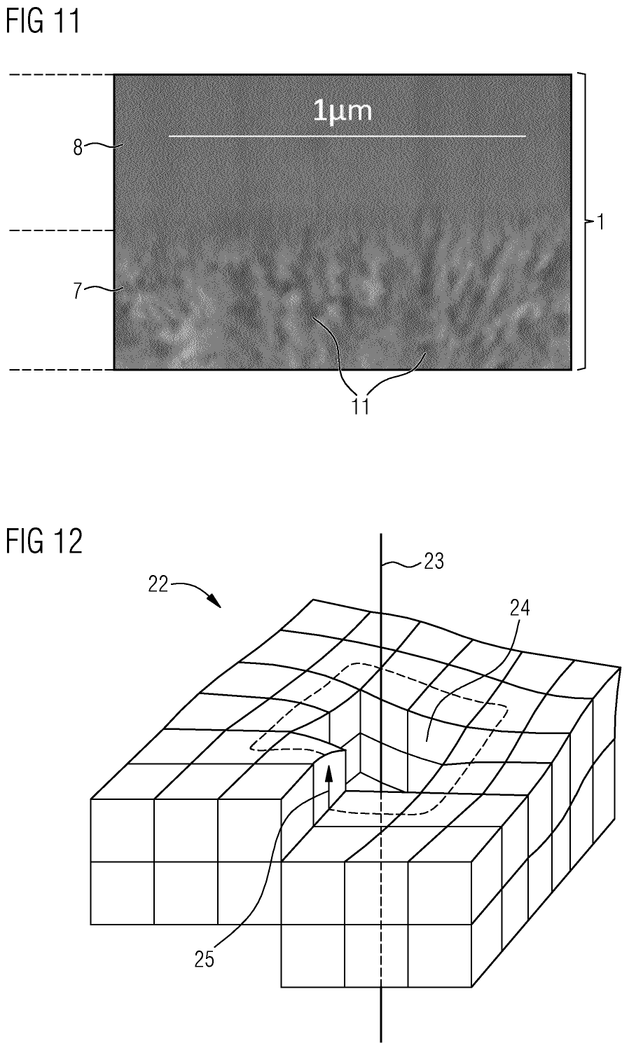

FIG. 11 shows a section of an epitaxial semiconductor layer sequence 1 comprising an undoped top layer 8 made of gallium nitride and an n-doped semiconductor layer 7 made of gallium nitride. More specifically, the n-doped semiconductor layer 7 comprises pores 11, which were created by electrochemical etching of the epitaxial semiconductor layer sequence 1. The liquid etchant 14 has penetrated the n-doped semiconductor layer 7 through threading dislocations 5 in the top layer 8.

The perspective view in FIG. 12 schematically shows a threading dislocation 5 in a cubic crystal lattice, which is formed as a screw dislocation 22. The screw dislocation 22 is a disruption of the periodicity of the crystal lattice and extends along a dislocation line 23 through the crystal. More specifically, the screw dislocation 22 has a hollow core 24 that is free of atoms of the crystal lattice. Crystal planes that are intersected by the dislocation line 23 are connected to each other in a helical shape. The screw dislocation 22 is characterized by a Burgers vector 25 which points in the direction of the dislocation line 23. More specifically, the screw dislocation 22 is a topological defect in the crystal lattice, which may be detected by determining the Burgers vector 25 even if the hollow core 24 of the screw dislocation 22 has been widened by wet chemical etching.

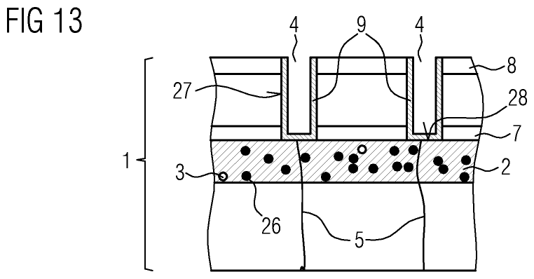

FIG. 13 shows a section of an epitaxial semiconductor layer sequence 1, where degassing channels 4 are partially filled with a dielectric 9 after the passivating material 3 has been expelled. In contrast to the semiconductor structure in FIG. 7, the degassing channels 4 are not completely filled with the dielectric 9 in this case. More specifically, side walls 27 of the degassing channels 4 are lined with the dielectric 9, while a core of the degassing channels 4 remains free of the dielectric 9. In addition, the bottom surfaces 28 of the degassing channels 4 may also be covered with the dielectric 9.

The invention is not limited to the description with reference to the embodiments. Rather, the invention encompasses any new feature as well as any combination of features, including in particular any combination of features in the claims, even if this feature or combination itself is not explicitly disclosed in the claims or embodiments.

1-17. (canceled)

18. A method for manufacturing a semiconductor structure, the method comprising:
epitaxially depositing an epitaxial semiconductor layer sequence comprising at least one p-doped semiconductor layer including a p-dopant and a passivating agent;
wet-chemical etching of the epitaxial semiconductor layer sequence so that degassing channels are formed along crystal defects in the epitaxial semiconductor layer sequence from a main surface of the epitaxial semiconductor layer sequence up to at least the p-doped semiconductor layer; and
expelling the passivating agent from the epitaxial semiconductor layer sequence through the degassing channels.

19. The method according to the claim 18, wherein the epitaxial semiconductor layer sequence comprises a nitride compound semiconductor material.

20. The method according to claim 18, wherein the epitaxial semiconductor layer sequence comprises an n-doped semiconductor layer, which is arranged between the p-doped semiconductor layer and the main surface of the epitaxial semiconductor layer sequence.

21. The method according to claim 18, wherein the crystal defects are formed as threading dislocations in the epitaxial semiconductor layer sequence during epitaxial deposition, and wherein the crystal defects have a main direction of extension corresponding to a growth direction of the epitaxial semiconductor layer sequence.

22. The method according to claim 21, wherein the threading dislocations are formed as screw dislocations having a hollow core.

23. The method according to claim 18, wherein epitaxial depositing is performed such that the crystal defects in the epitaxial semiconductor layer sequence are formed in a random arrangement.

24. The method according to claim 18, wherein the p-dopant is activated by expelling the passivating agent.

25. The method according to claim 18, wherein the main surface of the epitaxial semiconductor layer sequence is formed as a surface of an undoped top layer.

26. The method according to claim 18, wherein the degassing channels are at least partially filled with a dielectric after the passivating agent has been expelled.

27. A semiconductor structure comprising:
an epitaxial semiconductor layer sequence comprising at least one p-doped semiconductor layer; and
a plurality of degassing channels,
wherein the degassing channels are widened crystal defects, and
wherein the degassing channels in the epitaxial semiconductor layer sequence extend from a main surface of the epitaxial semiconductor layer sequence up to at least the p-doped semiconductor layer.

28. The semiconductor structure according to claim 27, wherein the epitaxial semiconductor layer sequence comprises an active layer, which is configured to generate and/or absorb electromagnetic radiation.

29. The semiconductor structure according to claim 27, wherein the epitaxial semiconductor layer sequence comprises pores, which are arranged laterally around the degassing channels.

30. The semiconductor structure according to claim 27, wherein the degassing channels penetrate the p-doped semiconductor layer.

31. The semiconductor structure according to claim 27, wherein the p-doped semiconductor layer forms a layer of a tunnel junction.

32. The semiconductor structure according to claim 31, wherein the epitaxial semiconductor layer sequence comprises two active layers configured to generate electromagnetic radiation between which the tunnel junction is arranged.

33. The semiconductor structure according to claim 31, wherein the degassing channels have a greater lateral dimension in a region of an n-doped semiconductor layer of the tunnel junction than in a remaining epitaxial semiconductor layer sequence so that tips in the n-doped semiconductor layer are formed due to the greater lateral dimension.

34. The semiconductor structure according to claim 27, wherein the degassing channels are at least partially filled with a dielectric.
